(19) United States
(12) Patent Application Publication
(10) Pub. No.: US 2024/0195229 A1
(43) Pub. Date: Jun. 13, 2024

(54) ELECTRONIC DEVICE FOR WIRELESS CHARGING IN MAGNETIC RESONANCE TYPE

(71) Applicant: Samsung Electronics Co., Ltd., Suwon-si (KR)

(72) Inventors: Wooram LEE, Suwon-si (KR); Yusu KIM, Suwon-si (KR)

(21) Appl. No.: 18/584,418

(22) Filed: Feb. 22, 2024

Related U.S. Application Data
(63) Continuation of application No. PCT/KR2022/014908, filed on Oct. 4, 2022.

(30) Foreign Application Priority Data
Dec. 7, 2021 (KR) 10-2021-0173556
Feb. 24, 2022 (KR) 10-2022-0024047

(51) Int. Cl. H02J 50/60; G01R 29/08; G06V 40/10; H02J 50/12; H02J 50/80

(52) U.S. Cl. CPC H02J 50/60; G06V 40/10; H02J 50/12; H02J 50/80; G01R 29/0878

(57) ABSTRACT

A power receiving device comprises: a camera; a coil configured to resonate at a designated frequency; a power receiving circuit configured to rectify a power signal received from a power transmitting device through the coil; a wireless communication circuit for wireless communication with the power transmitting device; at least one processor, comprising processing circuitry, electrically connected to the camera, the coil, the power receiving circuit, and the wireless communication circuit; and a memory connected to the processor. At least one processor, individually and/or collectively, is configured to: receive identification information for identifying the exterior of the power transmitting device from the power transmitting device through the wireless communication circuit; receive first notification information to notify the proximity of an object from the power transmitting device through the wireless communication circuit; identifying a first object corresponding to the power transmitting device, based on the identification information, from an image received from the camera, in response to receiving the first notification information; determine whether a second object corresponding to a human body exists in the image; and transmit second notification information indicating that the approaching object is a human body, to the power transmitting device through the wireless communication circuit, based on the first object being identified from the image, and based on the second object being deemed to exist in the image.

### CROSS-REFERENCE TO RELATED APPLICATIONS

This application is a continuation of International Application No. PCT/KR2022/014908 designating the United States, filed on Oct. 4, 2022, in the Korean Intellectual Property Receiving Office and claiming priority to Korean Patent Application Nos. 10-2021-0173556, filed on Dec. 7, 2021, and 10-2022-0024047, filed on Feb. 24, 2022, in the Korean Intellectual Property Office, the disclosures of each of which are incorporated by reference herein in their entireties.

### BACKGROUND

### Field

The disclosure relates to a device, a method, and a system for detecting the approach of a human body in a space (or using a magnetic resonant method) wireless charging system.

### Description of Related Art

In a wireless charging system using a magnetic inductive method, in the state in which a reception coil of a power reception device (RX) has approached a transmission coil of a power transmission device (TX), a battery that is electrically connected to the reception coil can be charged. In a space or spaced wireless charging system, the battery can be charged although the reception coil of the RX is spaced apart from the transmission coil of the TX by several meters.

In the spaced wireless charging system, the current of a power signal that is applied to the transmission coil may be increased as a distance between the TX and the RX becomes distant. An increase of the current may cause an increase of the strength of an electromagnetic field that is generated in the transmission coil. When a human body approaches the space wireless charging system while wireless charging is performed, a specific absorption rate (SAR) indicating a degree that electromagnetic waves are absorbed by the human body may be greater than a regulation value.

A sensor (e.g., a coil) that is used to detect the approach of a human body may be provided in a power transmission device. The power transmission device may manage the SAR to be less than a regulation value by adjusting a current based on detection data (e.g., an impedance change of a transmission coil) that are generated by the sensor. However, when the sensor is used, whether an object that has approached a space wireless charging system is a human body may be ambiguous.

### SUMMARY

Embodiments of the disclosure, provide a power reception device that can accurately detect whether an object that has approached a space wireless charging system is a human body. Power to be transmitted by a power transmission device can be adjusted so that a human body that has approached the system is not adversely affected.

According to an example embodiment, a power reception device includes: a camera, a coil configured to resonate in a designated frequency, a power reception circuit configured to rectify a power signal received from a power transmission device through the coil, a wireless communication circuit configured to perform wireless communication with the power transmission device, at least one processor, comprising processing circuitry, electrically connected to the camera, the coil, the power reception circuit, and the wireless communication circuit, and memory connected to at least one processor. At least one processor, individually and/or collectively, is configured to: receive identification information for identifying an outward appearance of the power transmission device from the power transmission device through the wireless communication circuit; receive first notification information to notify the proximity of an object from the power transmission device through the wireless communication circuit; identify a first object corresponding to the power transmission device based on the identification information in an image received from the camera in response to the reception of the first notification information; determine whether a second object corresponding to a human body is present in the image; transmit second notification information indicating that the approaching object is the human body to the power transmission device through the wireless communication circuit based on determining that the first object is identified in the image and the second object is present in the image.

According to an example embodiment, a power transmission device includes: a coil configured to resonate in a designated frequency, a power transmission circuit configured to output a power signal to the coil by converting the power signal into a power signal having the frequency and to adjust a current of a power signal to be output to the coil, a wireless communication circuit configured to perform wireless communication with the power reception device, and a control circuit electrically connected to the coil, the power transmission circuit, and the wireless communication circuit. The control circuit may be configured to: monitor a characteristic associated with the power signal supplied from the power transmission circuit to the power reception device through the coil; transmit first notification information to notify the proximity of an object to the power reception device through the wireless communication circuit based on first characteristic data obtained through the monitoring operation; receive second notification information indicating that the approaching object is a human body as a response to the first notification information having been transmitted to the power reception device; and control the power transmission circuit to lower the current of the power signal transmitted to the coil or to suspend the transmission of the power signal to the coil in response to the second notification information having been received from the power reception device.

According to various example embodiments, the electronic device can adjust a current value of power or suspend the transmission of power so that a human body is not adversely affected when a user enters an electromagnetic wave influence area, and can warn the user so that the user gets out of the electromagnetic wave influence area. In addition, various effects which may be checked directly or indirectly through this disclosure may be provided.

### BRIEF DESCRIPTION OF THE DRAWINGS

The above and other aspects, feature and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a block diagram illustrating an example configuration of a power management module and a battery according to various embodiments;

FIG. 3 is a block diagram illustrating an example configuration of a wireless communication module, power management module, and antenna module of the electronic device according to various embodiments;

FIG. 4 is an exploded perspective view illustrating a mobile electronic device including a bar type housing structure according to various embodiments;

FIG. 5 is a diagram illustrating an example spaced wireless charging system according to various embodiments;

FIGS. 6A and 6B are diagrams illustrating various examples in which the mobile electronic device in FIG. 5 outputs a message that induces a user to get out of an electromagnetic wave influence area according to various embodiments; and

FIG. 7 is a signal flow diagram illustrating example operations of the spaced wireless charging system in FIG. 5 according to various embodiments.

### DETAILED DESCRIPTION

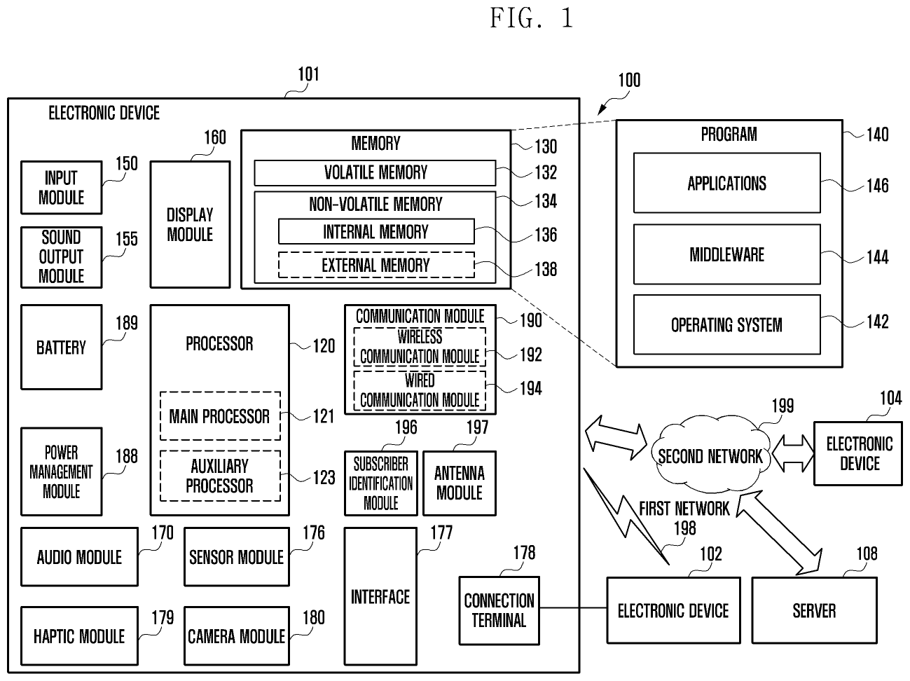

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

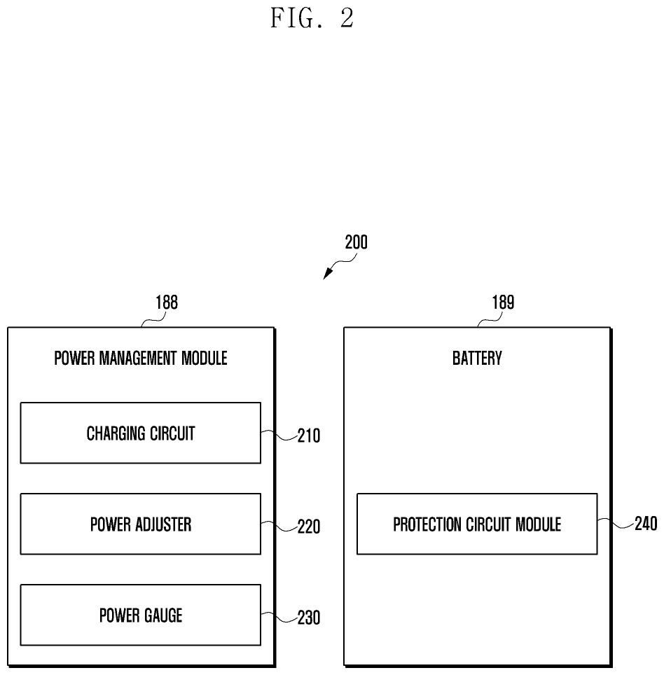

FIG. 2 is a block diagram 200 illustrating an example configuration of the power management module 188 and the battery 189 according to various embodiments. Referring to FIG. 2, the power management module 188 may include charging circuitry 210, a power adjuster 220, or a power gauge 230. The charging circuitry 210 may charge the battery 189 using power supplied from an external power source outside the electronic device 101. According to an embodiment, the charging circuitry 210 may select a charging scheme (e.g., normal charging or quick charging) based at least in part on a type of the external power source (e.g., a power outlet, a USB, or wireless charging), magnitude of power suppliable from the external power source (e.g., about 20 Watt or more), or an attribute of the battery 189, and may charge the battery 189 using the selected charging scheme. The external power source may be connected with the electronic device 101, for example, directly via the connecting terminal 178 or wirelessly via the antenna module 197.

The power adjuster 220 may generate a plurality of powers having different voltage levels or different current levels by adjusting a voltage level or a current level of the power supplied from the external power source or the battery 189. The power adjuster 220 may adjust the voltage level or the current level of the power supplied from the external power source or the battery 189 into a different voltage level or current level appropriate for each of some of the components included in the electronic device 101. According to an embodiment, the power adjuster 220 may be implemented in the form of a low drop out (LDO) regulator or a switching regulator. The power gauge 230 may measure use state information about the battery 189 (e.g., a capacity, a number of times of charging or discharging, a voltage, or a temperature of the battery 189).

The power management module 188 may determine, using, for example, the charging circuitry 210, the power adjuster 220, or the power gauge 230, charging state information (e.g., lifetime, over voltage, low voltage, over current, over charge, over discharge, overheat, short, or swelling) related to the charging of the battery 189 based at least in part on the measured use state information about the battery 189. The power management module 188 may determine whether the state of the battery 189 is normal or abnormal based at least in part on the determined charging state information. If the state of the battery 189 is determined to abnormal, the power management module 188 may adjust the charging of the battery 189 (e.g., reduce the charging current or voltage, or stop the charging). According to an embodiment, at least some of the functions of the power management module 188 may be performed by an external control device (e.g., the processor 120).

The battery 189, according to an embodiment, may include a protection circuit module (PCM) 240. The PCM 240 may perform one or more of various functions (e.g., a pre-cutoff function) to prevent a performance deterioration of, or a damage to, the battery 189. The PCM 240, additionally or alternatively, may be configured as at least part of a battery management system (BMS) capable of performing various functions including cell balancing, measurement of battery capacity, count of a number of charging or discharging, measurement of temperature, or measurement of voltage.

According to an embodiment, at least part of the charging state information or use state information regarding the battery 189 may be measured using a corresponding sensor (e.g., a temperature sensor) of the sensor module 176, the power gauge 230, or the power management module 188.. According to an embodiment, the corresponding sensor (e.g., a temperature sensor) of the sensor module 176 may be included as part of the PCM 240, or may be disposed near the battery 189 as a separate device.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

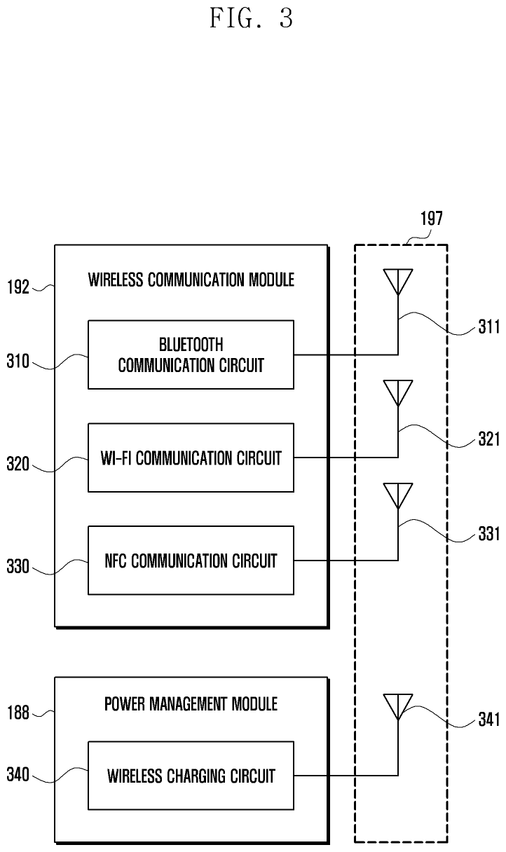

FIG. 3 is a block diagram illustrating an example configuration of the wireless communication module (e.g., including various circuitry) 192, power management module (e.g., including various circuitry) 188, and antenna module (e.g., including at least one antenna) 197 of the electronic device 101 according to an embodiment. Description of a component redundant with that of FIG. 1 may be omitted or simply described for convenience of description.

Referring to FIG. 3, the wireless communication module 192 may include a Bluetooth communication circuit 310, a Wi-Fi communication circuit 320, and an NFC communication circuit 330. The power management module 188 may include a wireless charging circuit 340. The antenna module 197 may include an antenna 311 connected to the Bluetooth communication circuit 310, an antenna 321 connected to the Wi-Fi communication circuit 320, an antenna 331 connected to the NFC communication circuit 330, and an antenna 341 connected to the wireless charging circuit 340. According to an embodiment, at least one of functions of the Bluetooth communication circuit 310, the Wi-Fi communication circuit 320, the NFC communication circuit 330, and the wireless charging circuit 340 may be controlled by the processor 120 (e.g., the main processor 121 and/or the auxiliary processor 123).

Each of the wireless communication circuits 310 to 330 may perform data communication with an external electronic device through a corresponding antenna based on control of the processor 120. For example, each of the wireless communication circuits 310 to 330 may establish a wireless communication channel (or a session) having a designated frequency band for data communication between the electronic device 101 and an external electronic device, and may perform data communication with the external electronic device through the established channel. At least one of the wireless communication circuits 310 to 330 may support data communication for wireless charging. For example, the processor 120 may perform at least one of procedures (e.g., selection, ping, identification, configuration, calibration, negotiation, and renegotiation) for wireless charging, which have been regulated in wireless power consortium (WPC) standards (or Qi standards), using at least one of the wireless communication circuits 310 to 330. In an embodiment, the processor 120 may be implemented using a method that is defined in alliance for wireless power (A4WP) standards (or air fuel alliance (AFA) standards) using at least one of the wireless communication circuits 310 to 330. For example, the electronic device 101 may include a power source, a DC-AC conversion circuit, an amplification circuit, an impedance matching circuit, at least one capacitor, at least one coil, an out-of-band communication circuit (e.g., the Bluetooth communication circuit 310, or a Bluetooth low energy (BLE) communication circuit), etc. The at least one capacitor and the at least one coil may constitute a resonant circuit.

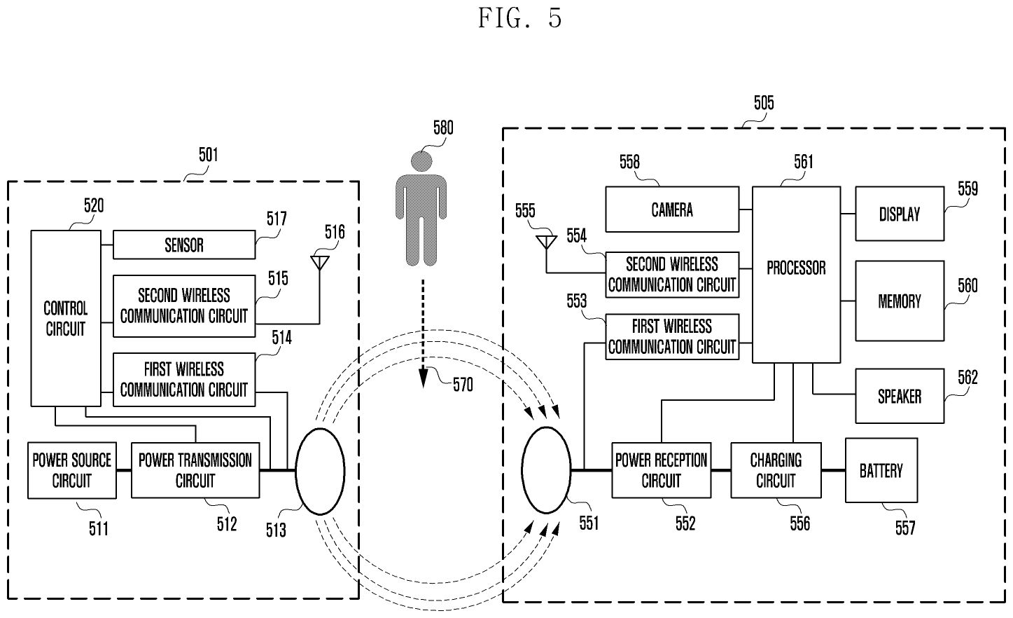

In an embodiment, the electronic device 101 may perform communication according to an out-of-band method. A power transmission device (e.g., a power transmission device 501 in FIG. 5) or a power reception device (e.g., a mobile electronic device 505 in FIG. 5) may transmit and receive data using a communication circuit (e.g., a BLE communication module) that is provided separately from a coil or a patch antenna. For example, the electronic device 101 may obtain information (e.g., a voltage value, a current value, various packets, authentication information, notification information and/or a message) related to a charging state using any one of various short-distance communication methods (e.g., the Bluetooth communication circuit 310, the Wi-Fi communication circuit 320, or the NFC communication circuit 330).

The wireless charging circuit 340 (e.g., the charging circuit 210 in FIG. 2) may wirelessly transmit power to the external electronic device 102 (e.g., a mobile phone or a wearable device) or may wirelessly receive power from the external electronic device 102 (e.g., a wireless charging device) through the antenna 341. The wireless charging circuit 340 may include a circuit for converting a characteristic of a current. For example, the wireless charging circuit 340 may include a rectification circuit for outputting, to a battery, a power signal that is received from an external electronic device through the antenna 341 by rectifying the power signal and an inverter circuit for outputting, to the antenna 341, the current of a power signal to be transmitted to an external electronic device by converting the current from direct current (DC) to alternating current (AC). The wireless charging circuit 340 may support one or more of various wireless charging methods including a magnetic resonant method or a magnetic inductive method, for example. The wireless charging circuit 340 may support data communication for wireless charging. For example, the processor 120 may perform at least one of procedures for wireless communication, which have been regulated in the WPC standards, using the wireless charging circuit 340.

Various housing structures may be applied to a mobile electronic device (e.g., the electronic device 101 in FIG. 1). For example, the mobile electronic device may have a bar type housing structure, a foldable housing structure, or a slidable (or rollable) housing structure. In an embodiment, the bar type housing structure may include a first cover that forms a front surface of a mobile electronic device, a second cover that forms a rear surface of the mobile electronic device, and a side bezel structure that forms a side surface of the mobile electronic device. In an embodiment, the foldable housing structure may include a first housing, a second housing, and a hinge assembly that enables the two housings to be rotatable. In the foldable housing structure, a first part of a display (e.g., a flexible display) may be disposed in the first housing, and a second part of the display may be disposed in the second housing. The foldable housing structure may be implemented in an in-folding way in which the first part and the second part face each other when a mobile electronic device is folded. Alternatively, the foldable housing structure may be implemented in an out-folding way in which the first part and the second part face against each other when the mobile electronic device is folded. In an embodiment, the slidable housing structure may include a housing, a slider part, and a roller that enables a part of the slider part to enter the housing or enables a part of the slider part to be drawn from the housing. As the slider enters the housing, a part of a display (e.g., a flexible display) may enter the housing.

In the disclosure, a surface of a display (e.g., a flexible display), which is visible to a user, may be denoted as a front surface (or a first surface) of a mobile electronic device. Furthermore, a surface opposite to the front surface may be denoted as a rear surface (or a second surface) of the mobile electronic device. Furthermore, a surface that surrounds a space between the front surface and the rear surface may be denoted as a side surface of the mobile electronic device. In an embodiment, the mobile electronic device may further include a separate sub-display that is visible through the rear surface.

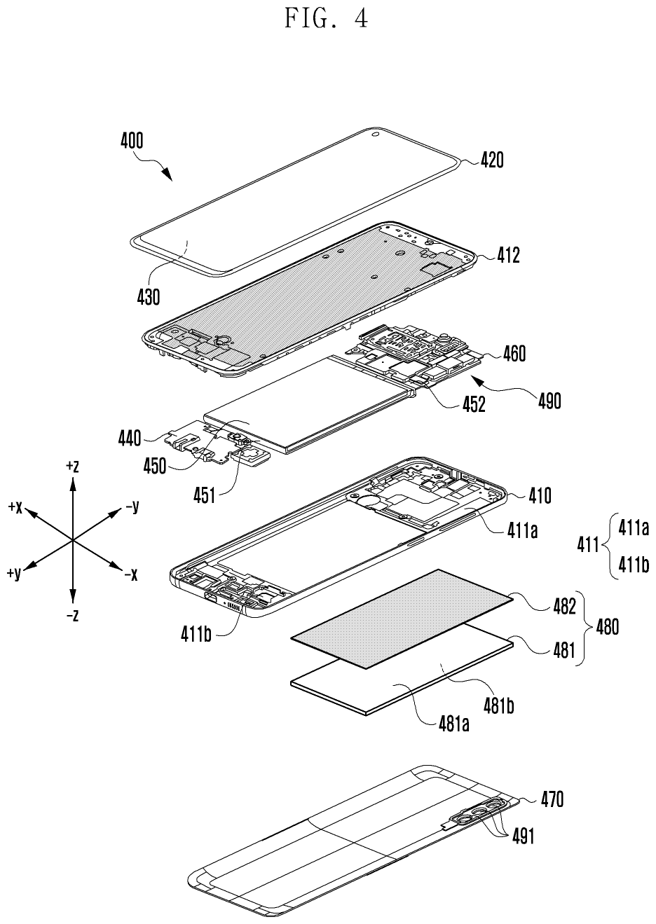

FIG. 4 is an exploded perspective view illustrating a mobile electronic device 400 including a bar type housing structure according to various embodiments.

Referring to FIG. 4, a mobile electronic device 400 (e.g., the electronic device 101 in FIG. 1) may include a side bezel structure (or a side frame) 410, a first support member (or a first support frame) 411, a second support member (or a second support frame) 412, a front plate (or a front cover) 420, a display 430 (e.g., the display module 160 in FIG. 1), at least one printed circuit board 440 and 460, a battery pack 450 (e.g., the battery 189 in FIG. 2), a rear plate (or a rear cover) 470, and an antenna structure 480. The front plate 420 may form a front surface of the mobile electronic device 400 that is directed toward a first direction (a +z axis direction in FIG. 4). The rear plate 470 may form a rear surface of the mobile electronic device 400 that is directed toward a second direction (a −z axis direction in FIG. 4) that is opposite to the first direction. The side bezel structure 410 may be formed of a combination of metal (e.g., SUS) and polymer, and may form a side surface that surrounds a space between the front surface and the rear surface. According to an embodiment, a structure including the front surface, the rear surface, and the side surface may be denoted as a housing structure. In an embodiment, at least one (e.g., the first support member 411 or the second support member 412) of the components of the mobile electronic device 400 may be omitted, or another component may be additionally included in the mobile electronic device 400.

The printed circuit board 440 and 460 may be disposed to be supported by the first support member 411 and/or the second support member 412. The first support member 411 may be combined with the side bezel structure 410. The first support member 411 may include a structure (e.g., metal and/or polymer) extended from the side bezel structure 410. The first support member 411 may be formed of metal and/or a non-metal material (e.g., polymer), for example. The display 430 may be combined with one surface of the second support member 412, and the printed circuit board 440 and 460 may be combined with the other surface of the second support member 412. According to an embodiment, the printed circuit board 440 and 460 may include a first substrate (or a sub-substrate) 440 and a second substrate (or a main substrate) 460 that are disposed on both sides thereof, respectively, with the battery pack 450 interposed therebetween. For example, the first substrate 440 may be disposed adjacently to a first side 451 of the battery pack 450 that is directed toward a +y axis direction. The second substrate 460 may be disposed adjacently to a second side 452 of the battery pack 450 that is directed toward a −y axis direction. The first support member 411 may include a second substrate support member 411a that supports the second substrate 460 and a first substrate support member 411b that supports the first substrate 440. The battery pack 450 may be disposed to be supported by the first support member 411 and/or the second support member 412. The battery pack 450 may include a rechargeable secondary cell as a device for supplying power to at least one component of the electronic device 400. The battery pack 450 may be disposed between the first substrate 440 and the second substrate 460. The battery pack 450 may be disposed substantially on the same plane as the printed circuit board 440 and 460.

The antenna structure 480 may include a flexible printed circuit board (FPCB) 481 and a shielding sheet 482. The FPCB 481 may include at least one antenna (e.g., the antennas 311, 321, 331, and 341 in FIG. 3). In this case, an antenna (e.g., wireless charging the antenna 341) may be a spiral type coil that is wound clockwise and/or counterclockwise around the z axis. The FPCB 481 may further include a magnetic material for inducing a magnetic flux generated by the antenna into the second direction (the −z axis direction). The FPCB 481 may include a plurality of layers. The antenna and/or the magnetic material may be partially formed in each layer. The shielding sheet 482 may induce a magnetic flux generated by the antenna of the FPCB 481 into the second direction (the −z axis direction) and shield a magnetic flux from the battery pack 450 and the printed circuit board 440 and 460 because the shield sheet 482 is disposed between the printed circuit board 440 and 460 and the FPCB 481. For example, the shielding sheet 481 may be attached to one surface 481a of the FPCB 481. The rear cover 470 may be attached to the other surface 481b of the FPCB 481.

A camera 490 may be disposed in the second substrate 460. For example, the camera 490 may include a plurality of lenses, image sensors, image signal processors, or flashes. The lenses of the camera 490 may be directed toward the second direction (the −z axis direction), and may be visually exposed through camera holes 491 formed in the rear cover 470.

Although not illustrated, the antenna structure 480 may be constructed in a mobile electronic device having a foldable housing structure or a slidable housing structure.

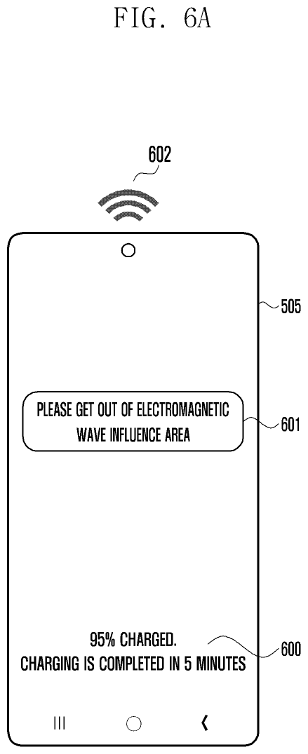

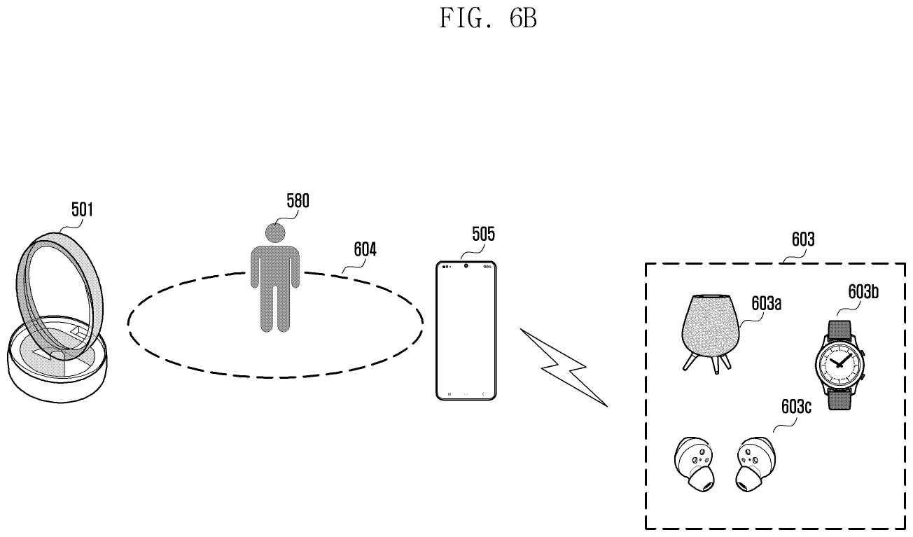

FIG. 5 is a block diagram illustrating an example configuration of a spaced wireless charging system according to various embodiments. FIGS. 6A and 6B are diagrams illustrating various examples in which the mobile electronic device 505 in FIG. 5 outputs a message that induces a user to get out of an electromagnetic wave influence area according to various embodiments. With reference to FIG. 5, the electronic device 501 (e.g., the electronic device 102 in FIG. 1) may wirelessly transmit power. The mobile electronic device 505 (e.g., the electronic device 101 in FIG. 1 or the mobile electronic device 400 in FIG. 4) may wirelessly receive power. The electronic device (hereinafter the power transmission device) 501 may include a power source circuit 511, a power transmission circuit 512, a power transmission coil 513, a first wireless communication circuit 514, a second wireless communication circuit 515, an antenna 516, a sensor 517, and a control circuit 520. The mobile electronic device (hereinafter the power reception device) 505 may include a power reception coil 551, a power reception circuit 552, a first wireless communication circuit 553, a second wireless communication circuit 554, an antenna 555, a charging circuit 556, a battery 557, a camera 558, a display 559, memory 560, a processor (e.g., including processing circuitry) 561, and a speaker 562.

The power circuit 511 may provide the power transmission device 501 with a power signal to be transmitted to the power reception device 505. For example, the power circuit 511 may include an adapter for converting the current of a power signal that is introduced from the outside from alternating current (AC) to direct current (DC) and outputting a voltage of power by adjusting the voltage to a designated voltage value based on control of the control circuit 520.

The power transmission circuit 512 may be configured to convert a current characteristic of a power signal that is received from the power circuit 511 from DC to AC in order to wirelessly transmit the power signal through the power transmission coil 513. For example, the power transmission circuit 512 may include an inverter circuit (e.g., a full bridge circuit) configured to periodically convert the direction of a current. The power transmission coil 513 may be configured to resonate in a specific frequency (e.g., a frequency that has been regulated in alliance for wireless power (A4WP) standards). The inverter circuit may generate a second power signal having a resonant frequency by periodically converting the current direction of a first power signal that is received from the power circuit 511 based on a resonant frequency of the power transmission coil 513, and may output the second power signal to the power transmission coil 513. Accordingly, the second power signal may be wirelessly transmitted to the power reception device 505 through the power transmission coil 513. The power transmission circuit 512 may include a current adjustment circuit (e.g., a low drop out (LDO) regulator) for transmitting the current of the second power signal to the power transmission coil 513 by adjusting the current based on control of the control circuit 520.

The power transmission coil 513 may be used as an antenna for data communication in addition to power transmission. Accordingly, the first wireless communication circuit 514 may perform data communication with the power reception device 505 through the power transmission coil 513. For example, the first wireless communication circuit 514 may receive a data signal from the control circuit 520, and may transmit the received data signal to the first wireless communication circuit 553 of the power reception device 505 by loading the received data signal onto a power signal. For example, a scheme for modulating the amplitude and/or frequency of a power signal may be used as a method of loading the data signal onto the power signal. The first wireless communication circuit 514 may receive a data signal from the first wireless communication circuit 553 of the power reception device 505 through a power signal that is delivered from the power transmission coil 513 to the power reception coil 551, and may deliver the received data signal to the control circuit 520.

The second wireless communication circuit 515 may perform data communication with the power reception device 505 through the antenna 516. For example, the second wireless communication circuit 515 may communicate with the second wireless communication circuit 554 of the power reception device 505 using any one of various short-distance communication methods, such as Bluetooth, Bluetooth low energy (BLE), Wi-Fi, and/or near field communication (NFC).

The sensor 517 may generate data that is used to recognize the approach of an external object. For example, the sensor 517 may be configured to include a coil. The coil of the sensor 517 may detect a change in the electromagnetic field that is formed by a power signal propagated by the power transmission coil 513, may generate data corresponding to a change in the electromagnetic field, and may deliver the data to the control circuit 520. The control circuit 520 may recognize the approach 570 of an external object (e.g., a human body 580) based on the data received from the sensor 517. In this case, the approach 570 of the external object may refer, for example, to the object entering an electromagnetic wave influence area (or an electromagnetic field) that has been formed between the two devices 501 and 505 as the power transmission device 501 transmits a power signal to the power reception device 505. If the object that has entered the influence area is a human body, electromagnetic waves greater than a regulation value may be absorbed by the human body.

The control circuit 520 (e.g., a microcontroller unit (MCU)) may be implemented as one chipset along with memory (not illustrated). The control circuit 520 may monitor a characteristic associated with a power signal. The monitored characteristic may include impedance of a transmission line from the power transmission coil 513 and/or the power transmission circuit 512 to the power transmission coil 513 and/or a characteristic (e.g., a voltage, a current, or a phase) of a power signal that is output from the power transmission circuit 512 to the power transmission coil 513, for example. The control circuit 520 may recognize the approach 570 of the external object based on the monitored characteristic having been changed.

The control circuit 520 may low adjust the current of a power signal value to be output from the power transmission circuit 512 to the power transmission coil 513 or suspend the transmission of the power signal to the power reception device 505, based on an approaching object being determined as the human body 580 (e.g., a hand or a face).

According to an embodiment, the control circuit 520 may monitor the current of a power signal that is output from the power transmission circuit 512 to the power transmission coil 513. The control circuit 520 may recognize a case in which the current reaches or is greater than a designated threshold value I_threshold as the approach 570 of an external object. The control circuit 520 may monitor impedance of the power transmission coil 513 while the power signal is transmitted to the power reception device 505 through the power transmission coil 513. The control circuit 520 may recognize a case in which the impedance reaches or is greater than the designated threshold value or a case in which the amount of change in the impedance reaches or is greater than the designated threshold value as the approach 570 of the external object. The control circuit 520 may receive detection data from the sensor 517, and may recognize, in the detection data, a change in the characteristic (e.g., a frequency, a current, or a voltage) of a power signal and/or a change in the characteristic (e.g., strength) of an electromagnetic field, which is propagated by the power transmission coil 513. The control circuit 520 may recognize a change in the characteristic, which is equal to or greater than a designated reference value, as the approach 570 of an external object. The control circuit 520 may transmit information (hereinafter first notification information) for providing notification of the approach 570 of an external object to the power reception device 505 through a wireless communication circuit (e.g., the first wireless communication circuit 514 or the second wireless communication circuit 515). The control circuit 520 may transmit identification information (e.g., a model name or an image indicative of an outward appearance (e.g., a contour) of the power transmission device 501) indicative of the power transmission device 501 and/or state information (e.g., a characteristic (e.g., a frequency, a current, or a voltage) indicative of the state of the power transmission device 501 of a power signal that is propagated by the power transmission coil 513 and/or impedance of the power transmission coil 513) to the power reception device 505 along with the first notification information. In this case, the identification information may have already been transmitted. For example, upon power delivery (PD) communication between the power transmission device 501 and the power reception device 505, the identification information may be delivered from the power transmission device 501 to the power reception device 505. The control circuit 520 may receive, from the power reception device 505, notification (hereinafter second notification information) indicating that an approaching object is the human body 580 through the first wireless communication circuit 514 or the second wireless communication circuit 515 as a response to the first notification information having been transmitted from the power transmission device 501 to the power reception device 505, from the power reception device 505. In response thereto, the control circuit 520 may control the power transmission circuit 512 to lower the current of a power signal to be output to the power transmission coil 513 up to a designated minimum value I-min (<the threshold value I_threshold).

According to an embodiment, in response to the second notification information having been received from the power reception device 505, the control circuit 520 may check whether the current of the power signal that is output from the power transmission circuit 512 to the power transmission coil 513 is greater than a designated limit value I_limit (>the threshold value I_threshold). When the current is equal to or greater than the limit value, the control circuit 520 may transmit state information indicating that the current is equal to or greater than the limit value to the power reception device 505 through a wireless communication circuit (e.g., the first wireless communication circuit 514 or the second wireless communication circuit 515), and may control the power transmission circuit 512 to suspend the output of the power signal to the power transmission coil 513. When the current is less than the limit value, the control circuit 520 may control the power transmission circuit 512 to lower the current of the power signal to be output to the power transmission coil 513 up to the designated minimum value I-min.

The control circuit 520 may transmit, to the power reception device 505, information (hereinafter third notification information) for providing notification that the current of a power signal is low adjusted or information (hereinafter fourth notification information) for providing notification that the transmission of a power signal is suspended through the first wireless communication circuit 514 or the second wireless communication circuit 515.

The control circuit 520 may determine that the human body 580 has deviated from an electromagnetic wave influence area based on data received from the sensor 517 and/or a change in a characteristic associated with the power signal. Based on such a determination, the control circuit 520 may control the power transmission circuit 512 to raise the current of a power signal that is output from the power transmission circuit 512 to the power transmission coil 513 from the minimum value I-min up to a set value (<the threshold value I_threshold) in order to transmit power to the power reception device 505. If power transmission has been suspendped, the control circuit 520 may control the power transmission circuit 512 to resume the power transmission.

The control circuit 520 may transmit, to the power reception device 505, information (hereinafter fifth notification information) for providing notification that the current of a power signal is high adjusted or information (hereinafter sixth notification information) for providing notification that the transmission of a power signal is resumed through the first wireless communication circuit 514 or the second wireless communication circuit 515.

The coil 551 of the power reception device 505 may be a spiral type coil that has been clockwise and/or counterclockwise wound around the z axis several times, which is included in the antenna structure 480 in FIG. 4, for example. The power reception coil 505 may receive a power signal from the power transmission device 501 through electrical coupling with the coil 513 of the power transmission device 501. For example, the power reception coil 551 may be configured to resonate in the same frequency as a frequency in which the power transmission coil 513 resonates.

The power reception circuit 552 (e.g., a rectification circuit) may include a rectification circuit that converts a current characteristic of a power signal that is received from the power transmission device 501 through the coil 551 from AC to DC, and may output the rectified power signal to the charging circuit 553.

The power reception coil 551 may be used as an antenna for data communication in addition to power reception. The first wireless communication circuit 553 may perform data communication with the power reception device 505 through the power reception coil 551. For example, the first wireless communication circuit 553 may receive a data signal from the processor 561, and may transmit the received data signal to the first wireless communication circuit 514 of the power transmission device 501 by loading the received data signal onto a power signal that is received from the power transmission coil 513. The scheme for modulating the amplitude and/or frequency of the power signal, which has been illustrated above, may be used as a method of loading the data signal onto the power signal. The first wireless communication circuit 553 may receive the data signal from the first wireless communication circuit 514 of the power transmission device 501 through the power signal that is delivered from the power transmission coil 513 to the power reception coil 551, and may deliver the received data signal to the processor 561.

The second wireless communication circuit 554 may perform data communication with the power transmission device 501 through the antenna 555. For example, the second wireless communication circuit 554 may communicate with the second wireless communication circuit 515 of the power transmission device 501 using any one of various short-distance communication methods, such as Bluetooth, Bluetooth low energy (BLE), Wi-Fi, and/or near field communication (NFC).

The charging circuit 556 (e.g., the charging circuit 210 in FIG. 2) may charge the battery 557 using a power signal received from the power transmission device 501 through the power reception circuit 552. For example, the charging circuit 556 may support constant current (CC) and constant voltage (CV) charging based on control of the processor 561. For example, while a charging mode is a CC mode, the charging circuit 556 may constantly maintain the current of a power signal, which is output from the charging circuit 556 to the battery 557, to a set charging current value by the processor 561 so that the voltage of the battery 557 rises up to a designated target voltage value. When the charging mode is changed from the CC mode to a CV mode as the voltage of the battery 557 reaches the target voltage value, the charging circuit 553 may maintain the voltage of the battery 557 to the target voltage value by stepwise lowering the current of the power signal that is output by the charging circuit 556 under the control of the processor 561. When the current of the power signal that is input to the battery 557 is lowered up to a designated charging completion current value (e.g., a topoff current value) while the battery 557 is charged in the CV mode, the charging circuit 556 may complete the charging of the battery 557 by suspending the output of the power signal to the battery 557 based on control of the processor 561. Instead of the charging circuit 556, the power transmission device 501 may support the CC and CV charging based on control of the processor 561. For example, the processor 561 may include various processing circuitry and determine whether the power transmission device 501 is a device capable of autonomously adjusting the current and voltage of a power signal by performing communication with the power transmission device 501 using the first wireless communication circuit 553 or the second wireless communication circuit 554. For example, the processor 561 may identify that the power transmission device 501 is a device capable of supporting CC and CV charging based on data (e.g., identification information indicating that the power transmission device 501 has a model having a programmable power supply (PPS) function) received from the power transmission device 501. Accordingly, the processor 561 may control the power transmission device 501 so that the power transmission device 501 support CC and CV charging through data communication with the power transmission device 501. Upon CC and CV charging using the power transmission device 501, the processor 561 may control the charging circuit 556 to output a received power signal to the battery 557 without adjusting the current and voltage.

Instructions for enabling a determination of whether an approaching object is the human body 580, enabling the power transmission device 501 to adjust the current value of transmission power or suspend power transmission so that the human body 580 is not adversely affected, and warning a user so that the user gets out of an electromagnetic wave influence area may be stored in the memory 560 (e.g., the memory 130 in FIG. 1), and may be executed by the processor 561.

The processor 561 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner At least one processor may execute program instructions to achieve or perform various functions. For example, the processor 561 may perform an operation of determining whether an approaching object is the human body 580 in response to the reception of the first notification information. According to an embodiment, in response to the reception of the first notification information, the processor 561 may activate the camera 558 so that the camera 558 captures an image and delivers the image to the processor 561. In an embodiment, the camera 558 may be in the state in which the camera has been activated before the first notification information is received by the processor 561. For example, while the battery 557 is charged using a power signal received from the power transmission device 501, the activation of the camera 558 may be maintained. While the camera 558 is already activated as described above, the processor 561 may receive the first notification information. The camera 558 may be a camera that is disposed in a direction in which a power signal is received and that is capable of photographing the power transmission device 501. For example, the camera 558 may be a rear camera (e.g., the camera 490 in FIG. 4) that is disposed on a rear surface of the power reception device 505, among a front surface and rear surface of the power reception device 505, along with the power reception coil 551. The processor 561 may identify a first object corresponding to the power transmission device 501, in an image received from the camera 558, using identification information of the power transmission device 501. The processor 561 may determine whether a second object corresponding to the human body 580 is present in the image received from the camera 558. When the first object is identified in the image and the second object is present in the image, the processor 561 may determine that the human body 580 is disposed in an electromagnetic wave influence area between the two devices 501 and 505, and may transmit the second notification information to the power transmission device 501 through the first wireless communication circuit 553 or the second wireless communication circuit 554 based on such a determination.

The processor 561 may receive the third notification information or the fourth notification information from the power transmission device 501 through the first wireless communication circuit 553 or the second wireless communication circuit 554 as a reply to the second notification information having been transmitted to the power transmission device 501. The processor 561 may deliver, to a user, a message that induces the user to get out of an electromagnetic wave influence area using an output device in response to the reception of the third notification information or the fourth notification information. With reference to FIG. 6A, the processor 561 may display a warning message 601 on the display 559 by including the warning message 601 in a screen 600 (e.g., a lock screen) that notifies the user of a degree of charging. Additionally or alternatively, the processor 561 may output a voice message 602 corresponding to the warning message 601 using the speaker 562. With reference to FIG. 6B, the processor 561 may transmit, to an external electronic device 603, a message that warns that the human body 580 is within an electromagnetic wave influence area 604 using a wireless communication circuit (e.g., the second wireless communication circuit 554). The external electronic device 603 (e.g., an AI speaker 603a, a smart watch 603b, and a wireless earphone 603c) may display the warning message on the display or output the voice message corresponding to the warning message through the speaker.

In an embodiment, the processor 561 may receive, from the power transmission device 501, the fifth notification information or the sixth notification information as the results of a response to a warning message from a user through the first wireless communication circuit 553 or the second wireless communication circuit 554. The processor 561 may suspend the output of the warning message in response to the reception of the fifth notification information or the sixth notification information. The processor 561 may determine a case in which the fifth notification information or the sixth notification information is not received for a designated time after the output of the warning message as the state in which the user does not respond or does not recognize the warning, and may transmit a message that requests the suspend of power transmission to the power transmission device 501 through the first wireless communication circuit 553 or the second wireless communication circuit 554 based on such a determination.

In an embodiment, when a second object corresponding to the human body 580 is not specified in an image received from the camera 558 (e.g., if the second object has disappeared from the image), the processor 561 may determine that a user has gotten out of an electromagnetic wave influence area in response to a warning message, and may transmit, to the power transmission device 501, a message that requests a current to be raised again or a message that requests the resumption of power transmission through the first wireless communication circuit 553 or the second wireless communication circuit 554 based on such a determination.

In an embodiment, the processor 561 may calculate a distance between the power transmission device 501 and an approaching object by processing an image received from the camera 558. The processor 561 may increase the accuracy of a determination using the calculated distance value as additional information for determining whether the approaching object is the human body 580. The processor 561 may calculate a distance between the power transmission device 501 and the power reception device 505 based on the strength (e.g., received signal strength indication (RSSI)) of a signal (e.g., a ping signal) received through the second wireless communication circuit 554 (e.g., a BLE communication circuit). The processor 561 may increase the accuracy of a determination using the calculated distance value between the two devices 501 and 505 as additional information for calculating the distance between the power transmission device 501 and the approaching object.

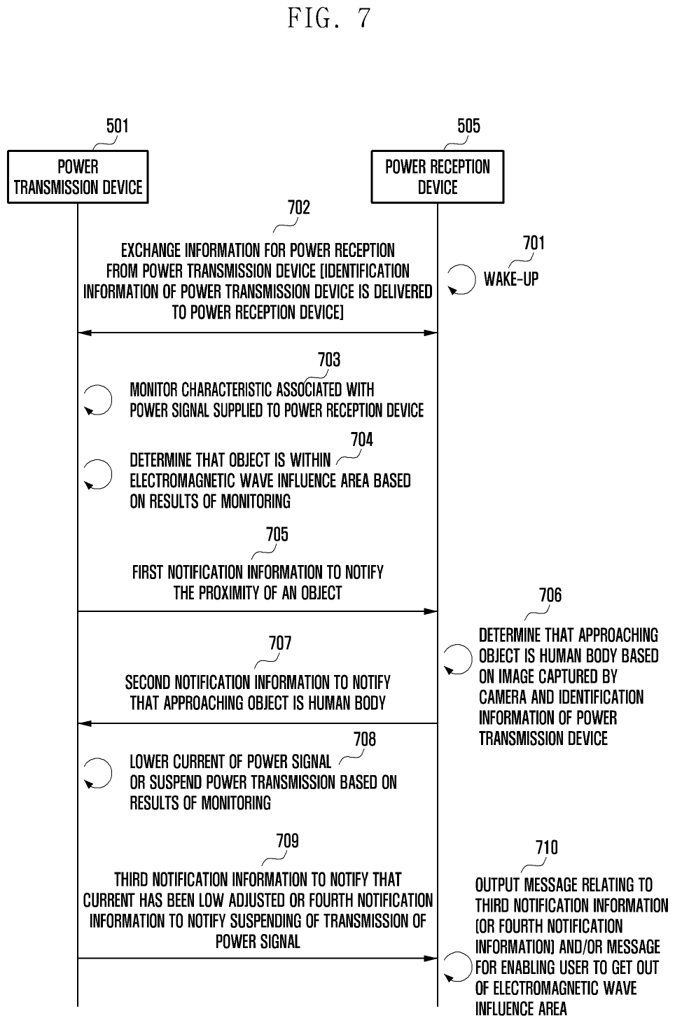

FIG. 7 is a signal flow diagram illustrating example operations of the spaced wireless charging system in FIG. 5 according to various embodiments.

At operation 701, the power reception device 505 may receive a wake-up signal that enables the power reception device 505 to start power reception from the power transmission device 501. For example, the processor 561 of the power reception device 505 may receive a power signal (e.g., a ping (or a beacon signal) that is periodically transmitted by the power transmission device 501 in order to find the power reception device 505) through the first wireless communication circuit 553 as the wake-up signal, and may activate the power reception circuit 552 in response to the reception of the wake-up signal. As another example, the processor 561 may receive the wake-up signal through a second wireless communication circuit (e.g., the BLE communication circuit) and activate the power reception circuit 552 in response thereto.

At operation 702, the processor 561 of the power reception device 505 may exchange information that is necessary for the power transmission device 501 to supply power to the power reception device 505 with the power transmission device 501 through the first wireless communication circuit 553 or the second wireless communication circuit 554 in response to the reception of the wake-up signal. For example, after receiving the wake-up signal from the power transmission device 501, the processor 561 may transmit, to the power transmission device 501, identification information (e.g., version information, a manufacturing code, or a basic device identifier) relating to the power reception device 505 and/or configuration information (e.g., a wireless charging frequency, maximum chargeable power, a required charging power quantity, or an average transmission power quantity) related to wireless charging through the first wireless communication circuit 553 or the second wireless communication circuit 554 as a response message for the wake-up signal. After the response message is transmitted to the power transmission device 501, the power transmission device 501 may transmit the identification information of the power transmission device 501 (e.g., a model name or an image indicative of an outward appearance (e.g., a contour) of the power transmission device 501) to the power reception device 505. Additionally, the power transmission device 501 may transmit state information (e.g., a characteristic (e.g., a frequency, a current, or a voltage) of a power signal that is propagated by the power transmission coil 513 and/or impedance of the power transmission coil 513) indicative of the state of the power transmission device 501 to the power reception device 505. Furthermore, the power signal may be received by the power reception circuit 552 of the power reception device 505 through the power reception coil 551. The processor 561 may control charging circuit 556 to charge the battery 557 using the received power signal. The power transmission device 501 may periodically transmit the wake-up signal by including the identification information of the power transmission device 501 in the wake-up signal.

At operation 703, the control circuit 520 of the power transmission device 501 may monitor a characteristic associated with the power signal that is supplied to the power reception device 505. As illustrated above, the monitored characteristic may include impedance of the power transmission coil 513 and/or a characteristic (e.g., a voltage, a current, or a phase) of the power signal that is output to the power transmission coil 513.

At operation 704, the control circuit 520 of the power transmission device 501 may determine that an object is within an electromagnetic wave influence area based on the results (characteristic data) that are obtained through the monitoring. For example, when the current of a power signal that is output from the power transmission circuit 512 to the power transmission coil 513 reaches or is greater than a designated threshold value I_threshold, the control circuit 520 may determine that the object is disposed within the electromagnetic wave influence area. As another example, when monitored impedance of the power transmission coil 513 reaches or is greater than the designated threshold value or the amount of change in the impedance reaches or is greater than the designated threshold value while the power signal is transmitted to the power reception device 505 through the power transmission coil 513, the control circuit 520 may determine that the object is disposed within the electromagnetic wave influence area. As still another example, the control circuit 520 may determine that the object is disposed within the electromagnetic wave influence area based on detection data received from the sensor 517.

At operation 705, the control circuit 520 of the power transmission device 501 may transmit the first notification information to notify the proximity of the object to the power reception device 505 through the first wireless communication circuit 514 or the second wireless communication circuit 515.

At operation 706, the processor 561 of the power reception device 505 may determine that the approaching object is a human body based on an image captured by the camera 558 and the identification information of the power transmission device 501. For example, the processor 561 may identify, in the image, a first object corresponding to the power transmission device 501 and a second object corresponding to the human body 580. If the first object and the second object are identified to be present in the image as described above, the processor 561 may determine that the human body 580 is disposed within the electromagnetic wave influence area between the two devices 501 and 505.

At operation 707, the processor 561 of the power reception device 505 may transmit, to the power transmission device 501, the second notification information indicating that the approaching object is the human body through the first wireless communication circuit 553 or the second wireless communication circuit 554 as a reply to the reception of the first notification information.

At operation 708, the control circuit 520 of the power transmission device 501 may lower the current of the power signal or may suspend power transmission based on the results of the monitoring in response to the reception of the second notification information. For example, the control circuit 520 may check whether the current of the power signal that is output from the power transmission circuit 512 to the power transmission coil 513 is greater than a designated limit value I_limit (>the threshold value I_threshold), and may control the power transmission circuit 512 to suspend the output of the power signal to the power transmission coil 513 when the current is equal to or greater than the limit value. When the current is less than the limit value, the control circuit 520 may control the power transmission circuit 512 to lower the current of the power signal to be output to the power transmission coil 513 up to a designated minimum value I-min.

At operation 709, the control circuit 520 of the power transmission device 501 may transmit, to the power reception device 505, the third notification information for providing notification that the current has been low adjusted or the fourth notification information for providing notification that the transmission of the power signal has been suspended through the first wireless communication circuit 514 or the second wireless communication circuit 515.

At operation 710, the processor 561 of the power reception device 505 may output a message (e.g., a message for providing notification of charging speed delay or a charging suspend) relating to the third notification information (or the fourth notification information) and/or a message for enabling a user to deviate from the electromagnetic wave influence area using an output device. For example, the processor 561 may perform an operation of displaying the warning message 601 in FIG. 6A on the display 559 and/or an operation of outputting the voice message 602 corresponding to the warning message 601 using the speaker 562. Additionally or alternatively, the processor 561 may transmit, to the external electronic device 603, a message that warns that the human body 580 is within the electromagnetic wave influence area using a wireless communication circuit (e.g., the second wireless communication circuit 554).

According to an example embodiment, a power reception device (e.g., the power reception device 505 in FIG. 5) includes: a camera, a coil configured to resonate in a designated frequency, a power reception circuit configured to rectify a power signal received from a power transmission device through the coil, a wireless communication circuit configured to perform wireless communication with the power transmission device, at least one processor, comprising processing circuitry, electrically connected to the camera, the coil, the power reception circuit, and the wireless communication circuit, and memory connected to at least one processor. At least one processor, individually and/or collectively, is configured to: receive identification information for identifying an outward appearance of the power transmission device from the power transmission device through the wireless communication circuit and receive (e.g., the operation 705) first notification information for providing notification of the approach of an object from the power transmission device through the wireless communication circuit; identify a first object corresponding to the power transmission device based on the identification information in an image received from the camera in response to the reception of the first notification information and to determine whether a second object corresponding to a human body is present in the image; transmit (e.g., the operation 707) second notification information indicating that the approaching object is the human body to the power transmission device through the wireless communication circuit based on determining that the first object is identified in the image and the second object is present in the image.

The power reception device further includes a display and/or a speaker as an output device. At least one processor, individually and/or collectively, is configured to: receive third notification information for providing notification that a current is low adjusted or fourth notification information for providing notification of a suspend of the transmission of the power signal from the power transmission device through the wireless communication circuit; and output a message that enables a user to get out of an electromagnetic wave influence area using the output device in response to the reception of the third notification information or the fourth notification information.

The wireless communication circuit may include a first wireless communication circuit configured to communicate with the power transmission device using the coil as an antenna, and a second wireless communication circuit configured to communicate with the power transmission device using a separate antenna. At least one processor, individually and/or collectively, may be configured to perform communication for power reception with the power transmission device using at least one of the first wireless communication circuit and the second wireless communication circuit.

At least one processor, individually and/or collectively, may be configured to: receive third notification information for providing notification that a current is low adjusted or fourth notification information for providing notification of a suspend of a transmission of a power signal from the power transmission device through the wireless communication circuit; and transmit a message that enables a user to get out of an electromagnetic wave influence area to an external electronic device through the second wireless communication circuit in response to the reception of the third notification information or the fourth notification information.

The second wireless communication circuit may be configured to support at least one short-distance wireless communication method, among Bluetooth, Bluetooth low energy (BLE), Wi-Fi, and near field communication (NFC).

The power reception device may further include a housing including a front surface and rear surface of the power reception device. The coil may be wound around an axis perpendicular to the rear surface several times. The camera may be disposed on the rear surface along with the coil.

According to an example embodiment, a power transmission device (e.g., the power transmission device 501 in FIG. 5) includes: a coil configured to resonate in a designated frequency, a power transmission circuit configured to output a power signal to the coil by converting the power signal into a power signal having the frequency and to adjust a current of a power signal to be output to the coil, a wireless communication circuit configured to perform wireless communication with the power reception device, and a control circuit electrically connected to the coil, the power transmission circuit, and the wireless communication circuit. The control circuit may be configured to: monitor a characteristic associated with the power signal supplied from the power transmission circuit to the power reception device through the coil; transmit first notification information for providing notification of the approach of an object to the power reception device through the wireless communication circuit based on first characteristic data obtained through the monitoring; receive second notification information indicating that the approaching object is a human body as a response to the first notification information having been transmitted to the power reception device; and control the power transmission circuit to lower the current of the power signal transmitted to the coil or to suspend the transmission of the power signal to the coil in response to the second notification information having been received from the power reception device.

The control circuit may be configured to transmit third notification information for providing notification that the current has been low adjusted or fourth notification information for providing notification of suspending of the transmission of the power signal to the power reception device through the wireless communication circuit.

The control circuit may be configured to, as part of the monitoring, monitor the current of the power signal output from the power transmission circuit to the coil, and transmit the first notification information based on the monitored current being equal to or greater than a designated threshold value.

The control circuit may be configured to, as part of controlling the power transmission circuit, control the power transmission circuit to lower the current of the power signal transmitted to the coil up to a minimum value designated as a value less than the threshold value based on the monitored current being less than a limit value designated as a value greater than the threshold value, and suspend the transmission of the power signal to the coil based on the monitored current being equal to or greater than the limit value.

The wireless communication circuit may include a first wireless communication circuit configured to communicate with the power reception device using the coil as an antenna and a second wireless communication circuit configured to communicate with the power reception device using a separate antenna. The control circuit may be configured to perform communication for a power supply with the power reception device using at least one of the first wireless communication circuit and the second wireless communication circuit.

The second wireless communication circuit may be configured to support at least one short-distance wireless communication method, among Bluetooth, Bluetooth low energy (BLE), Wi-Fi, and near field communication (NFC).

The power transmission device may further include a sensor. The monitoring may include receiving, by the control circuit, data from the sensor. The control circuit may be configured to determine whether to transmit the first notification information based on the data received from the sensor.

The control circuit may be configured to control the power transmission circuit to raise the current of the power signal transmitted to the coil or to resume the transmission of the power signal to the coil based on second characteristic data obtained through the monitoring operation, after performing the operation of controlling the power transmission circuit.

The control circuit may be configured to transmit fifth notification information for providing notification that the current has been high adjusted or sixth notification information for providing notification of the resumption of the transmission of the power signal to the power reception device through the wireless communication circuit.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A power reception device comprising:
a camera;
a coil configured to resonate at a designated frequency;
a power reception circuit configured to rectify a power signal received from a power transmission device through the coil;
a wireless communication circuit configured to perform wireless communication with the power transmission device;
a processor; and
memory storing instructions that, when executed by the processor, cause the power reception device to:
receive identification information for identifying an outward appearance of the power transmission device from the power transmission device through the wireless communication circuit,
receive first notification information for providing notification of an approach of an object from the power transmission device through the wireless communication circuit,
identify a first object corresponding to the power transmission device based on the identification information in an image received from the camera in response to the reception of the first notification information and determine whether a second object corresponding to a human body is present in the image, and
transmit second notification information indicating that the approaching object is the human body to the power transmission device through the wireless communication circuit based on determining that the first object is identified in the image and the second object is present in the image.

2. The power reception device of claim 1, further comprising a display and/or a speaker as an output device, wherein the instructions cause the power reception device to:
receive third notification information to notify that a current is low adjusted or fourth notification information for providing notification of suspension of the transmission of the power signal from the power transmission device through the wireless communication circuit, and
output a message that enables a user to get out of an electromagnetic wave influence area using the output device in response to the reception of the third notification information or the fourth notification information.

3. The power reception device of claim 1, wherein:
the wireless communication circuit comprises a first wireless communication circuit configured to communicate with the power transmission device using the coil as an antenna, and a second wireless communication circuit configured to communicate with the power transmission device using a separate antenna, and
the processor is configured to perform communication for power reception with the power transmission device using at least one of the first wireless communication circuit and the second wireless communication circuit.

4. The power reception device of claim 3, wherein the instructions cause the power reception device to:
receive third notification information to notify that a current is low adjusted or fourth notification information for providing notification of suspending of a transmission of a power signal from the power transmission device through the wireless communication circuit, and
transmit a message that enables a user to get out of an electromagnetic wave influence area to an external electronic device through the second wireless communication circuit in response to the reception of the third notification information or the fourth notification information.

5. The power reception device of claim 3, wherein the second wireless communication circuit is configured to support at least one short-distance wireless communication method, among Bluetooth, Bluetooth low energy (BLE), Wi-Fi, and near field communication (NFC).

6. The power reception device of claim 1, further comprising a housing comprising a front surface and rear surface of the power reception device,
wherein the coil is wound around an axis perpendicular to the rear surface multiple times, and
the camera is disposed on the rear surface along with the coil.

7. A power transmission device comprising:
a coil configured to resonate at a designated frequency;
a power transmission circuit configured to output a power signal to the coil by converting the power signal into a power signal having the frequency and to adjust a current of a power signal to be output to the coil;
a wireless communication circuit configured to perform wireless communication with the power reception device; and
a control circuit electrically connected to the coil, the power transmission circuit, and the wireless communication circuit,
wherein the control circuit is configured to:
monitor a characteristic associated with the power signal supplied from the power transmission circuit to the power reception device through the coil,
transmit first notification information to notify the proximity of an object to the power reception device through the wireless communication circuit based on first characteristic data obtained through the monitoring operation,
receive second notification information indicating that the approaching object is a human body in response to the first notification information transmitted to the power reception device, and
control the power transmission circuit to lower the current of the power signal transmitted to the coil or to suspend the transmission of the power signal to the coil in response to the second notification information having been received from the power reception device.

8. The power transmission device of claim 7, wherein the control circuit is configured to transmit third notification information for providing notification that the current has been low adjusted or fourth notification information for providing notification of the suspending of the transmission of the power signal to the power reception device through the wireless communication circuit.

9. The power transmission device of claim 7, wherein the control circuit is configured, as part of the monitoring operation, to:
monitor the current of the power signal output from the power transmission circuit to the coil, and
transmit the first notification information when the monitored current is equal to or greater than a designated threshold value.

10. The power transmission device of claim 9, wherein the control circuit is configured, as part of controlling the power transmission circuit, to:
control the power transmission circuit to lower the current of the power signal transmitted to the coil up to a minimum value designated as a value less than the threshold value based on the monitored current being less than a limit value designated as a value greater than the threshold value, and
suspend the transmission of the power signal to the coil based on the monitored current being equal to or greater than the limit value.

11. The power transmission device of claim 7, wherein:
the wireless communication circuit comprises a first wireless communication circuit configured to communicate with the power reception device using the coil as an antenna and a second wireless communication circuit configured to communicate with the power reception device using a separate antenna, and
the control circuit is configured to perform communication for a power supply with the power reception device using at least one of the first wireless communication circuit and the second wireless communication circuit.

12. The power transmission device of claim 11, wherein the second wireless communication circuit is configured to support at least one short-distance wireless communication method, among Bluetooth, Bluetooth low energy (BLE), Wi-Fi, and near field communication (NFC).

13. The power transmission device of claim 7, further comprising a sensor,
wherein the monitoring comprises receiving, by the control circuit, data from the sensor, and
the control circuit is configured to determine whether to transmit the first notification information based on the data received from the sensor.

14. The power transmission device of claim 7, wherein the control circuit is configured control the power transmission circuit to raise the current of the power signal transmitted to the coil or to resume the transmission of the power signal to the coil based on second characteristic data obtained through the monitoring operation, after controlling the power transmission circuit.

15. The power transmission device of claim 14, wherein the control circuit is configured to transmit fifth notification information for providing notification that the current has been high adjusted or sixth notification information to notify the resumption of the transmission of the power signal to the power reception device through the wireless communication circuit.
